(19) United States
(12) Patent Application Publication
(10) Pub. No.: US 2017/0278858 A1
(43) Pub. Date: Sep. 28, 2017

(54) MONOLITHIC 3-D DYNAMIC MEMORY AND METHOD

(71) Applicant: SCHILTRON CORPORATION, Mountain View, CA (US)

(72) Inventors: Andrew J. Walker, Mountain View, CA (US); Eli Harari, Saratoga, CA (US)

(21) Appl. No.: 15/465,556

(22) Filed: Mar. 21, 2017

Related U.S. Application Data
(60) Provisional application No. 62/311,802, filed on Mar. 22, 2016.

(51) Int. Cl. H01L 27/11578; G11C 11/22; H01L 27/11597; H01L 27/1159; H01L 27/1157; H01L 27/11573

(52) U.S. Cl. CPC H01L 27/11578; H01L 27/1157; H01L 27/11573; H01L 27/11597; H01L 27/1159; G11C 11/223; G11C 16/08

(57) ABSTRACT

A monolithic 3-D dynamic memory structure includes independently addressable strings of dual-gate devices. In each dual-gate device charge is deliberately stored on one side of the dual-gate. Although the stored charge may leak away, the stored charge in a dual-gate device of the present invention need only be refreshed at much longer intervals than conventional DRAM cells.

### CROSS REFERENCE TO RELATED APPLICATIONS

The present application relates to and claims priority of U.S. provisional patent application (“Provisional Application”), Ser. No. 62/311,802, entitled “Monolithic 3-D Dynamic Memory and Method,” filed Mar. 22, 2016. The disclosure of the Provisional Application is hereby incorporated by reference in its entirety.

### BACKGROUND OF THE INVENTION

1. Field of the Invention

The present invention relates to semiconductor structures for implementing memory circuits. In particular, the present invention relates to a 3-dimensional semiconductor structure for implementing a dynamic memory cell.

2. Description of the Related Art

Scaling of dynamic random access memory (DRAM) circuits is expected to reach a limit at close to 20 nm minimum feature size. (See, e.g., the article, entitled “Technology scaling challenge and future prospects of DRAM and NAND flash memory” by S.-K. Park, published in IEEE International Memory Workshop (IMW), 2015, and also, U.S. Pat. No. 5,511,020, entitled “Pseudo-Non Volatile Memory Incorporating Data Refresh Operation,” to Hu et al.).

One of the main challenges in DRAM cell design at that feature size is keeping the capacitance of the cell capacitor large enough to be sensed. As a result, approaches without using cell capacitors are being investigated (See, e.g., the article, entitled “Investigation of Capacitorless Double-Gate Single-Transistor DRAM: With and Without Quantum Well,” by M. G. Ertosun and K. C. Saraswat, published in IEEE Trans. Elect. Dev., vol. 57, pp. 608-613, March 2010). These capacitor-less approaches rely on storing charge in a diode-isolated semiconductor body of a transistor.

An alternative approach to a conventional DRAM cell is achieved by using charge stored in a dielectric. For example, the article entitled “High Endurance Ultra-Thin Tunnel Oxide for Dynamic Memory Application” (“Wann”), by C. H.-J. Wann and C. Hu, published in the IEEE International Electron Device Meeting (IEDM), pp. 867-870, 1995, discloses a very thin tunnel oxide in a “MONOS” structure (also known as a “SONOS” structure) that is measured to have a thickness of about 1.2 nm. The MONOS structure includes a silicon nitride layer that is sandwiched between a silicon dioxide layer and the very thin tunnel oxide layer (the “ONO” structure).

FIG. 1 shows device 100 which is a conventional MONOS transistor formed in and on crystalline bulk silicon 106 and which includes a charge storage structure formed by thermal tunnel oxide layer 101, nitride layer 102, and oxide layer, 103. Oxide layer 103 is typically deposited, such as by low-pressure chemical vapor deposition (LPCVD). In Wann's MONOS structure, thermal tunnel oxide 101 is grown to a thickness of about 1.2 nm, which is significantly thinner than typical MONOS/SONOS tunnel oxide that is usually between 1.6 nm and 3 nm. Examples of MONOS/SONOS transistors having the usual thicknesses are disclosed in (a) the article entitled “A Novel SONOS Structure for Nonvolatile Memories with Improved Data Retention,” H. Reisinger et al., published in VLSI Symposium, pp. 113-114, 1997; and (b) the article entitled “Narrow Distribution of Threshold Voltage in 4-Mbit MONOS Memory-Cell Array With F-N Channel Write and Direct/F-N Tunneling Erase Operation as a Single Transistor Structure,” by A. Nakamura et al., published in IEEE Trans. Elect. Dev., vol. 51, pp. 895-900, June 2004.

The reduced thickness in Wann's MONOS structure allows a lower voltage to be used for faster program and erase cycles and much higher endurance. Endurance was shown in Wann's MONOS structure to reach 10¹¹ program/erase cycles. The very high endurance is achieved because the thin tunnel oxide layer suffers significantly less tunneling damage than a thicker oxide would. However, the reduced damage is achieved at the expense of retention, since the stored charge will leak away. This leakage can be counter-acted through refreshing the data stored in each cell through re-programming at prescribed intervals. This refreshing can be at intervals of minutes, hours, days or months dependent on optimization of the ONO structure. In any case, the required refresh interval is much longer than that of conventional DRAM circuits, which are typically required to be refreshed at tens of milliseconds. The infrequent refresh operation under the MONOS structure provides a significant low-power advantage.

Thus, to achieve a long retention application (e.g., in a nonvolatile applications), thicker tunnel oxide and higher program and erase voltages are preferable. However, the higher programming and erase voltages result in a limited endurance in the memory cells. While greater endurance may be achieved with lower program and erase voltages, dynamically refresh operations may be required to maintain the program state of the memory cells in many applications.

When single-gate refreshable devices are placed in a string (i.e., so that the drain of each single-gate device is used as the source of a neighboring single-gate device), such as in a NAND string), to ensure that a current is passed to each single-gate device that is being read or programmed, a pass voltage is applied to the gates of all the other single-gate devices of the string. FIG. 2 illustrates reading of a memory cell in contactless string 200 of conventional MONOS transistors 201-1 to 201-n (n=3, for illustratively purpose only). Each of MONOS transistors 201-1 to 201-n are formed in thin film layer 202, which includes source or drain regions 204-1, . . . , 204-(n+1), with the source or drain region between any two adjacent MONOS transistors being shared between the two adjacent MONOS transistors.

As shown FIG. 2, to read MONOS transistor 201-2, a “read-pass” voltage is imposed on the gate terminals of all the MONOS transistors 201-1 . . . 201-n, except for the gate terminal of MONOS transistor 201-2, which is imposed a “read” voltage. The presence or absence of a conduction current indicates the charge state of MONOS transistor to be read (in this case, MONOS transistor 201-2). The “read pass” voltage needs to be high enough such that (i) the MONOS transistors in the string receiving the “read pass” voltage is conducting and (ii) a sufficiently large string current is present even if the device being read (e.g., MONOS transistor 201-2) is in the erased state. Such a process is disclosed, for example, in the article, entitled “Sub-50-nm Dual-Gate Thin-Film Transistors for Monolithic 3-D Flash,” by A. J. Walker, IEEE Trans. Elect. Dev., vol. 56, November 2009, pp. 2703-2710. Since each device in the string can be programmed or erased at a low voltage, the “read-pass” voltages can easily disturb the stored charge contents of each cell. Methods to avoid program disturb in dual-gate devices are disclosed, for example, in U.S. Pat. No. 7,339,821 by Andrew J. Walker entitled “Dual-gate nonvolatile memory and method of program inhibition” which is incorporated in its entirety in this application.

What is desired is a 3-dimensional memory structure that stacks memory cells of the smallest memory footprint configuration (e.g., a contactless string) that is highly disturb-resistant. Furthermore, it is desired that such memory cells attain a high enough memory density that is at least comparable and preferably superior to that of conventional DRAM cells.

### SUMMARY

According to one embodiment of the present invention, a monolithic 3-D dynamic memory structure includes independently addressable strings of thin-film dual-gate devices. In each thin-film dual-gate device charge is stored on one side of the dual-gate. A channel region of this dual-gate storage device may be provided on a single-crystal substrate or a nano-poly-crystal substrate). Although the stored charge may leak away, the stored charge in a dual-gate device of the present invention need only be refreshed at much longer intervals than conventional DRAM cells.

One advantage of the present invention is enhanced program and erase (P/E) endurance levels, while operating with reduced P/E voltages. Because dual-gate devices are used, the memory cells of the present invention—which are configured as strings in a memory structure of the smallest footprint—may be read or programmed while minimizing the disturbs on the memory cells connecting up to the one being read or programmed.

The present invention is better understood upon consideration of the detailed description below in conjunction with the accompanying drawings.

### BRIEF DESCRIPTION OF THE DRAWINGS

FIG. 1 shows device 100 which is a conventional MONOS transistor in crystalline bulk silicon.

FIG. 2 illustrates reading of a memory cell in contactless string 200 of conventional MONOS transistors 201-1 to 201-n (n=3, for illustratively purpose only).

FIG. 3 show dual-gate contactless string 300 including dual-gate devices 301-1, . . . , 301-n (n=3, for illustratively purpose only), in accordance with one embodiment of the present invention.

FIG. 4 is a block diagram of memory circuit 400 in which the dual gate memory devices of the present invention may be used.

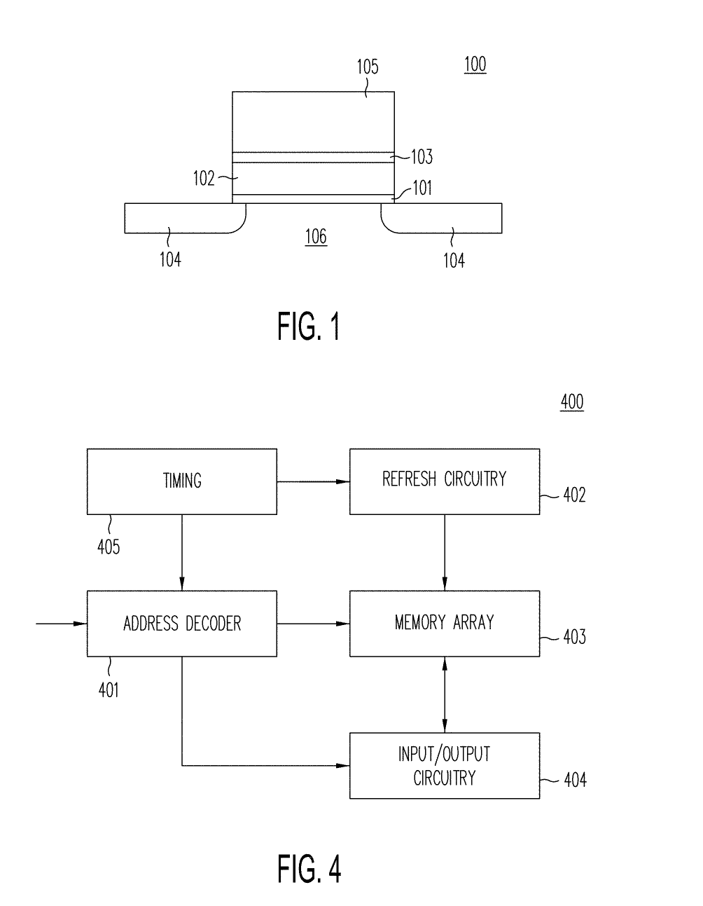

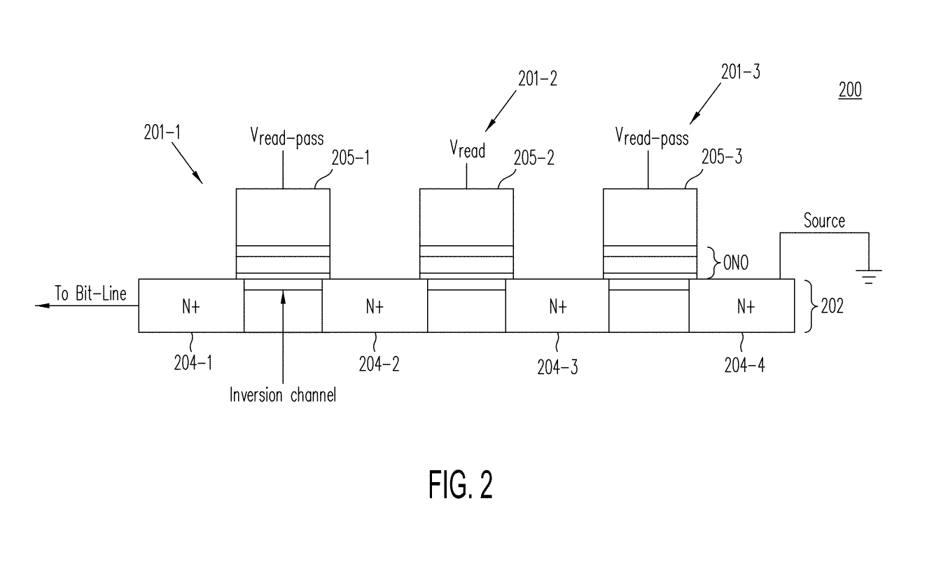

### DETAILED DESCRIPTION OF THE PREFERRED EMBODIMENTS

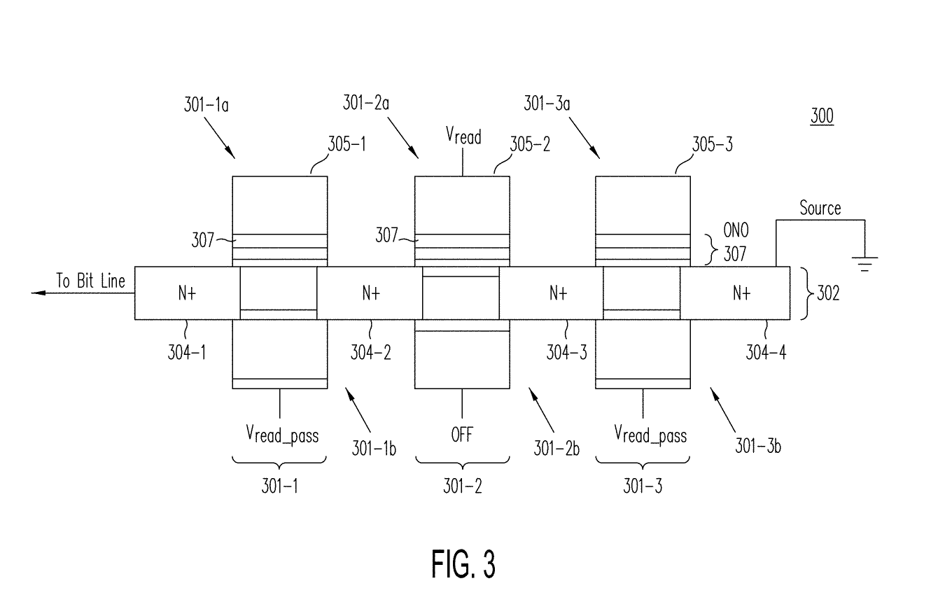

The present invention provides a memory cell and a method that overcome the difficulties of the prior art. FIG. 3 shows dual-gate contactless string (“NAND string”) 300 including dual-gate devices 301-1, . . . , 301-n (n=3, for illustratively purpose only), in accordance with one embodiment of the present invention. As shown in FIG. 3, dual-gate transistors 301-1, . . . , 301-n are formed in conjunction with a silicon substrate, referred herein as thin-film layer 302. Active devices (e.g., 301-2a and 301-2b) are formed one on each side of thin film layer 302, between a pair of drain or source regions (e.g., 304-2 and 304-3). In FIG. 3, charge storage layer 307, typically an oxide-nitride-oxide (ONO) layer is provided in one of the active devices (“storage devices,” e.g., active devices 301-1a. 301-2a and 301-3a) on the side of thin-film layer 302 opposite that of the access devices. Active devices formed on the other side of substrate or thin-film layer 302 (e.g., active devices 301-1b, 301-2b and 301-3b, referred to as “access devices”), are used for accessing the storage devices for reading, writing and erase operations. According to one embodiment of the present invention, charge storage ONO layer 307 of each storage device includes an ultra-thin tunnel oxide layer (e.g., between 0 nm and 2 nm); this tunnel oxide layer is the oxide layer in the ONO structure that is closest to the semiconductor channel. The nitride layer may be implemented by any charge trapping dielectric material such as silicon nitride, silicon oxynitride, hafnium oxide or any combinations thereof. The top oxide on the other side of the nitride layer opposite the side facing the semiconductor channel may be, for example, a silicon dioxide, aluminum oxide, hafnium oxide, or any combination thereof.

To read the charge stored in storage device 301-2a, for example, a “read-pass” voltage is imposed on the gate terminals of all the access devices 301-1b . . . 301-nb, except for the gate terminal of access device 301-2b. The gate terminals may be organized into word lines that are selected by decoding a “row” address, for example A “read” voltage V_{read} is imposed on storage device 301-2a. The source or drain regions in thin-film layer 302 at the two ends of the NAND string are coupled to a bit line and a reference source voltage, respectively. The bit lines allow data to be written into or read from the memory cells. The bit lines are selected by decoding a “column” address. In a dual-gate device, such as dual-gate device 301-2, the value of a conduction current indicates the charge state of storage device 301-2a, which is being read. For example, when read voltage V_{read} is chosen to be between the erased and programmed states of storage device 301-2a, the presence or absence of a conduction current indicates the charge state of storage device 301-2a being read. In the dual-gate transistor, the inversion channel and the depletion layer of the access device provide shielding from the “read pass” voltage V_{read}_{_}ₚₐₛₛ imposed on the gate terminal of the access transistor, thereby preventing disturbance to the charge stored in the corresponding storage device on the other side of thin film layer 302. Furthermore, the dual-gate transistor inherently provides a close electrostatic interaction between the access device and the storage device, thereby providing good short-channel control. Thus, the dual-gate approach allows access to the charge state of each storage device through the access devices without any pass disturbs. In some embodiments, techniques that reduce program and erase voltages, or techniques that speed up program and erase operations are used. As discussed above, devices that operate under reduced program and erase voltages may have short retention time and thus require refresh at predetermined time intervals.

Dual-gate devices with horizontal gates (i.e., gates that are provided along a direction parallel to the silicon substrate) used for non-volatile memory applications are discussed, for example, in U.S. Pat. Nos. 7,612,411, 7,410,845, 7,339,821, 7,459,755, 7,777,268 and 7,777,269. Dual gate devices with vertical gates (i.e., gates that are aligned in a direction perpendicular to the silicon substrate) used for non-volatile memory applications are discussed, for example, in a U.S. provisional patent application, Ser. No. 62/194,713, which is incorporated herein in its entirety.

Alternatively, the charge storage layer in the storage devices may be implemented by a silicon-rich oxide (SRO) sandwich between a tunneling oxide between 0 nm and 3 nm thick, and a top oxide. The SRO is either deposited or is an oxide that is implanted with silicon. The SRO layer is disclosed for example, “A Long-Refresh Dynamic/Quasi-Nonvolatile Memory Device with 2-nm Tunneling Oxide,” by Y.-C. King, et al., published in IEEE Elect. Dev. Left., vol. 20, pp. 409-411, August 1999.

Another option for the charge storage layer in the storage device is a nanocrystal layer. The nano-crystal layer is formed by embedding or implanting conducting or semiconducting nanocrystals in an oxide between the gate of the storage device and the semiconductor channel. The nanocrystal layer may be made of metals or silicon, germanium or a combination thereof. The nanocrystals may be located between 0.1 nm and 3 nm from the semiconductor channel.

Another option for a thin-film transistor-based dynamic memory uses the ferroelectric nature of a hafnium oxide material that may be provided in the gate dielectric. This technique is disclosed, for example, in “Ferroelectricity in Hafnium Oxide: CMOS Compatible Ferroelectric Field Effect Transistors,” by T. S. Boscke et al., IEDM, pp. 547-550, 2011.

Still another option for the charge storage layer in the storage device is a sandwich structure between the memory gate and the semiconductor channel in which a bottom oxide layer is implanted with a non-doping species (e.g., silicon, germanium, or krypton) which enhances the tunneling current through the tunnel oxide, lowers the program and erase voltages and speeds up the program and erase operation. (Again, the trade-off is lower retention; see, e.g., the disclosures of U.S. Pat. Nos. 4,868,618 and 5,371,027.) Under this approach the tunnel oxide may be between 0.1 nm and 4.0 nm. For conformal implantation on sidewalls of channels with vertical gates (as disclosed in U.S. provisional patent application, Ser. No. 62/194,713, mentioned above), plasma immersion ion implantation (PIII) or plasma doping (PLAD) techniques may be used. The non-doping species may be implanted into the tunnel dielectric directly or through a thin layer of silicon (poly or amorphous) covering the tunnel dielectric. Techniques for implantation are disclosed, for example, in the article entitled “Ion beam mixing for enhanced electron tunneling in metal-oxide-silicon structures,” by A. J. Walker et al., Appl. Phys. Lett., vol. 62, pp. 768-760, August 1993.

A variation to any approach given above includes: using thin-film channel material that is junction-less, i.e., either: (a) the channel is doped with one type of dopant (either n-type or p-type); or (b) the same doping step is used to dope the regions along the channel between each dual-gate device and between the access device and its associated memory device within each dual-gate device.

A further variation in any of the above approaches involves the methods to crystallize the thin-film channel material to maximize the electric current flow through the devices. These methods include: (a) thermal treatments; (b) metal-induced crystallization; (c) laser crystallization such as with excimer lasers.

Yet a further variation of any approach given above that simplifies process manufacturing includes the case where charge storage dielectrics are placed on both the access devices and the memory devices of each dual-gate device but where the access devices' ability to store charge is not used as the memory element.

FIG. 4 is a block diagram of memory circuit 400 in which the dual gate memory devices of the present invention may be used. In FIG. 4, dual gate memory devices may be organized in memory array 403 into NAND strings, with each memory device in each NAND strings being addressable by a memory address. By convention, each memory address includes a portion which specifies a row or “word line” address which identifies the control or gate terminals of the memory devices in one or more NAND strings to be read simultaneously, and a column or “bit line” address which identifies the data terminals of the memory devices addressed. According to one embodiment of the present invention, during a read, program or erase operation, address decoder 401 receives and decodes a memory address to provide control signals to memory array 403 to allow data in the addressed memory devices to be output into input/output circuit 404, data in input/out circuit 404 to be stored into the addressed memory devices, or the memory devices addressed to be erased. In FIG. 4, refresh circuit 402 systematically refreshes the data in all the memory devices with valid data. The term “refresh” refers to the reading of data from these memory devices and the writing of the read data back into the memory devices within a predetermined time interval (“refresh cycle”) that is less than the expected data retention time of the memory devices, so as to prevent data loss. Timing circuit 405 provides timing signals to sequence the access of the memory devices for read, write, erase and refresh operations.

The above detailed description is provided to illustrate the specific embodiments of the present invention and is not intended to be limiting. Numerous variations and modifications within the scope of the present invention are possible. The present invention is set forth in the accompanying claims.

We claim:

1. A thin-film storage device, comprising:
a thin-film semiconductor substrate having a first surface and a second surface opposite the first surface; and
a dual-gate device comprising:
a first field-effect device having a channel region at the first surface of the semiconductor substrate, a gate conductor, and a gate dielectric layer provided between the channel region and the gate conductor, the gate dielectric layer capable of storing an amount of electric charge or ferroelectricity, wherein a threshold voltage of the field effect device is determined by the stored amount of electric charge or ferroelectricity, and wherein a refresh circuit is coupled to the first field-effect device to refresh the charge or ferroelectricity in the gate dielectric layer at prescribed times; and
a second field-effect device having a channel region at the second surface of the semiconductor substrate.

2. The thin-film storage device of claim 1, wherein at least one of the first and second field effect devices comprises a junctionless device.

3. The thin-film storage device of claim 1, wherein the channel region of at least one of the first and second field effect devices is formed between a first source or drain region and a second source or drain region, both the first and second source or drain regions being formed in the thin-film semiconductor substrate.

4. The thin-film storage device of claim 1, wherein the gate dielectric layer comprises a oxide-nitride-oxide layer.

5. The thin-film storage device of claim 2, the oxide-nitride-layer comprises an oxide layer that is less than 2.0 nm thick.

6. The thin-film storage device of claim 1, wherein the gate dielectric layer comprises a tunneling oxide, a silicon-rich oxide and a top oxide.

7. The thin-film storage device of claim 6, wherein the top oxide comprises a silicon dioxide, aluminum oxide, hafnium oxide, or any combination thereof

8. The thin-film storage device of claim 6, wherein the tunneling oxide is between 0 nm and 3.0 nm thick.

9. The thin-film storage device of claim 1, wherein the gate dielectric layer comprises nanocrystals.

10. The thin-film storage device of claim 9, wherein the nanocrystals are comprises metals, silicon, germanium or a combination thereof.

11. The thin-film storage device of claim 9, wherein the nanocrystals are located between 0.1 nm and 3 nm from the semiconductor channel.

12. The thin-film storage device of claim 1, wherein the gate dielectric layer comprises a tunneling oxide layer that is implanted with a non-doping species.

13. The thin-film storage device of claim 12, wherein the non-doping species includes any one of silicon, germanium, and krypton.

14. The thin-film storage device of claim 12, wherein the tunnel oxide is between 0.1 nm and 4.0 nm thick.

15. The thin-film storage device of claim 1, wherein the gate conductor is formed generally parallel to a plane of the semiconductor substrate.

16. The thin-film storage device of claim 1, wherein the gate conductor is formed generally perpendicular to a plane of the semiconductor substrate.

17. The thin-film storage device of claim 1, wherein the channel region is formed generally parallel to a plane of the semiconductor substrate.

18. The thin-film storage device of claim 1, wherein the channel region is formed generally perpendicular to a plane of the semiconductor substrate.

19. The thin-film storage device of claim 1, wherein the second field-effect device further comprises a gate conductor, and a gate dielectric layer provided between the channel region and the gate conductor, the gate dielectric layer capable of storing an amount of electric charge or ferroelectricity.

20. The thin-film storage device of claim 19, wherein a threshold voltage of the second field effect device is determined by the stored amount of electric charge or ferroelectricity stored in the gate dielectric layer, and wherein a refresh circuit is coupled to the second field-effect device to periodically refresh the charge or ferroelectricity in the gate dielectric layer.

21. The thin-film storage device of claim 1, wherein the dual-gate device being one of a plurality of dual-gate device forming a string of memory devices.

22. The thin-film storage device of claim 21, wherein the thin-film storage device is one of a plurality of strings of memory devices.

23. The thin-film storage device of claim 21, wherein the channel region of the first field-effect device is doped n-type.

24. The thin-film storage device of claim 1, wherein the gate dielectric layer of the first field-effect device comprises hafnium oxide.

25. The thin-film storage device of claim 24, wherein the ferroelectricity is provided by the hafnium oxide.
